(19) United States
(12) Patent Application Publication
(10) Pub. No.: US 2013/0023062 A1
(43) Pub. Date: Jan. 24, 2013

(54) THIN FILM MANUFACTURING APPARATUS, THIN FILM MANUFACTURING METHOD AND METHOD FOR MANUFACTURING SEMICONDUCTOR DEVICE

(71) Applicants: Takeshi Masuda, Shizuoka (JP); Masahiko Kajinuma, Shizuoka (JP); Nobuyuki Kato, Shizuoka (JP); Koukou Suu, Shizuoka (JP)

(72) Inventors: Takeshi Masuda, Shizuoka (JP); Masahiko Kajinuma, Shizuoka (JP); Nobuyuki Kato, Shizuoka (JP); Koukou Suu, Shizuoka (JP)

(21) Appl. No.: 13/515,246

(22) PCT Filed: Nov. 30, 2010
(86) PCT No.: PCT/JP2010/071372

§ 371 Date: Sep. 28, 2012

(30) Foreign Application Priority Data
Dec. 11, 2009 (JP) 2009-282239

(51) Int. Cl. C23C 16/22; H01L 21/02

(52) U.S. Cl. 438/3; 118/715; 118/724; 118/712; 427/255.28; 257/E21.008

(57) ABSTRACT

In an apparatus for manufacturing a ceramic thin film by employing a thermal CVD method, an internal jig, which is provided with a heat radiation material film on the surface, is provided at a position that faces a substrate (S) on which the film is to be formed. The thin film and a semiconductor device are manufactured using such apparatus.

### TECHNICAL FIELD

The present invention relates to a thin film manufacturing apparatus, a thin film manufacturing method, and a method for manufacturing a semiconductor device which comprises the thin film and, in particular, to a thin film manufacturing apparatus, a method for manufacturing a ceramic (or ceramics) thin film such as a PZT thin film and a method for manufacturing a semiconductor device which comprises a ceramic thin film such as a PZT thin film.

### BACKGROUND ART

There has recently been used a thin film of, for instance, lead zirconate titanate (Pb (Zrₓ, Ti₁₋ₓ) O₃; this will hereunder be referred to as “PZT”) having a perovskite-like structure as a ferroelectric thin film used, for instance, in the ferroelectric memory such as DRAM (dynamic random access memory) or the like and in a dielectric filter, since it shows, for instance, a high residual polarization and ferroelectricity.

Regarding the method for the manufacture of a ferroelectric film consisting of such a PZT thin film, there has been investigated the metal organic chemical vapor deposition (hereunder referred to as “MOCVD”) technique as a method for manufacturing, at a good reproducibility, a PZT thin film or the like, which is a film almost free of any defect and has high quality, and which is excellent in the step coverage characteristics and in the uniformity (or in-plane uniformity) on the surface of a large scale substrate.

Among the CVD processes wherein a desired film is deposited on the surface of a substrate through the reaction of raw materials for forming the thin film within a high temperature atmosphere, the foregoing MOCVD technique is one in which an organometal compound is used as a raw material and in which a desired film is formed while reacting a gasified organometal compound with a reactive gas (an oxidizing gas or a reducing gas) (see, for instance, Patent Documents 1 and 2 specified below). In Patent Document 1, Pb(thd)₂, Zr(dmhd)₄ and Ti(i-PrO)₂(thd)₂ are used as raw materials, and a desired film is formed by reacting these organometal compounds as the raw materials with an oxidizing gas while changing, with the elapse of time, the concentration of the latter. On the other hand, in Patent Document 2, a desired film is formed while using Pb(CH₃COO)₂.3H₂O, Zr(t-BuO)₄ and Ti(i-PrO)₄ as the raw materials.

In addition, also known is a method which comprises the step of supplying a mixed gas consisting of a gaseous raw material, an oxidizing gas and a dilution gas onto the surface of a substrate and allowing them to cause a reaction therebetween to thus form an intended oxide film (see, for instance, Patent Document 3 specified below). In Patent Document 3, such a desired film is formed while using, as raw materials or starting organometal compounds, Pb(thd)₂, Zr(dmhd)₄ and Ti(i-PrO)₂(thd)₂.

Furthermore, there has also been known a method for forming a PZT thin film while using a gaseous raw material consisting of organometal compounds selected from the group consisting of Pb (thd)₂, Zr(thd)₄, Zr(dmhd)₄, Ti(i-PrO)₂(thd)₂, Zr(mmp)₄, and Ti(mmp)₄, and a reactive gas (see, for instance, Patent Document 4 specified below).

Still further, there has been known a thin film manufacturing apparatus and a method for the manufacture of a thin film, which can reduce the number of particles possibly formed in the resulting film during the film-forming steps (see, for instance, Patent Documents 5 and 6 specified below). In Patent Documents 5 and 6, a film having a small number of particles is formed using Pb(dpm)₂, Zr(dmhd)₄, and Ti(i-PrO)₂(dpm)₂ as raw materials or starting organometal compounds and an oxygen gas as a reactive gas.

### PRIOR ART LITERATURE

### Patent Document

Patent Document 1: Japanese Un-Examined Patent Publication No. 2003-324101;
Patent Document 2: Japanese Un-Examined Patent Publication No. 2005-150756;
Patent Document 3: Japanese Un-Examined Patent Publication No. 2004-273787;
Patent Document 4: Japanese Un-Examined Patent Publication No. 2005-166965;
Patent Document 5: Japanese Un-Examined Patent Publication No. 2005-054252; and
Patent Document 6: Japanese Un-Examined Patent Publication No. 2005-054253.

### DISCLOSURE OF THE INVENTION

### Problems That the Invention Is To Solve

When manufacturing a ceramic thin film such as those discussed above, it would be common that after mounting or attaching a washed and/or cleaned internal jig, the temperature inside of a film-forming apparatus is raised up to the desired film-forming temperature and then a film-forming process is carried out under the same process conditions used for the practical or intended film-forming process (operating conditions used when manufacturing an intended product), while flowing raw gases, a reactive gas, a carrier gas and a dilution gas through the apparatus as a preliminary step for preparing an intended product. More specifically, the film manufacturing apparatus is operated till the temperature of any part of the jigs arranged within the apparatus reaches a predetermined level for obtaining the intended product and then the film manufacturing process is carried out in order to manufacture the intended product. The substrate used in this preliminary step is referred to as a “dummy substrate” and it is common that the preliminary step is carried out till a film is formed on a plurality of dummy substrates while using, as such dummy substrates, ones almost identical to those used for the practical or intended film manufacturing steps. In other words, the preliminary film manufacturing step is continued over not less than 100 dummy substrates till the film manufacturing apparatus can provide a stable or uniform film to thus give an intended product. The film manufacturing conditions used for such a preliminary step are identical to those used for the practical and intended film manufacturing step, but the temperature of every portions within the film manufacturing apparatus never uniformly reaches a predetermined level unless a large number of dummy substrates are processed. For this reason, there has been desired for the development of a technique required for reducing the number of dummy substrates to be used from the viewpoints of the reduction of the time required for the processing step and of economy.

On the other hand, when it is tried to mass-produce a ceramic thin film such as a PZT thin film according to the thermal CVD technique such as the MOCVD technique, it would be quite important for the establishment of strict reproducibility of the film-manufacturing operation to control the substrate temperature upon the manufacture of such a thin film. However, problems arise such that the substrate temperature is changed with time and that the control of the substrate temperature is thus quite difficult, for the following reasons.

When forming a ceramic thin film other than a metal thin film on the surface of a substrate according to the MOCVD technique, the jigs arranged around the substrate, in particular, parts (such as shower plate), which are arranged in positions facing the substrate in the case of the single wafer processing type film manufacturing apparatus, are warmed by the radiant heat emitted from the substrate and this in turn results in the film formation on the surface of such parts like the film formation on the substrate surface. The occurrence of the possible formation of such film on the parts would results in a change in the rate of reflection with respect to the radiant heat emitted from the substrate and this accordingly leads to an undesirable change in the surface temperature of the substrate. In this respect, it is difficult to directly monitor the surface temperature of the substrate according to the existing techniques and the temperature of the substrate surface is controlled, in the latter techniques, through the determination or the monitoring of the temperature of a substrate-supporting stage, which is a circular flat part called susceptor on which the substrate is to be placed, by bringing a thermocouple into close contact with the face of the susceptor opposite to that carrying the substrate (i.e., the back of the susceptor), or through the determination or the monitoring of the temperature of the space in the very proximity to the susceptor. For this reason, it would be difficult that any change in the surface temperature of the substrate per se is directly reflected in the control of the temperature thereof. In not only the cases in which the film-forming process is carried out while using a novel part, but also the cases wherein the film-forming process is carried out while replacing the used parts arranged within the film-forming chamber and provided with films formed thereon with washed and/or cleaned ones, the temperature of the substrate to be placed within the film-forming chamber may vary from one substrate to another substrate if the film-forming process is initiated immediately after the foregoing operations and accordingly, a problem arises such that this inevitably causes changes in the composition and/or film thickness (film-forming rate) of the resulting ceramic thin film such as a PZT thin film.

Accordingly, it has been tried to conduct the temperature control by mounting or attaching a jig for heat-exchange to a part to be exchanged such as a shower plate or by equipping the part with the jig in order to cool the latter in such a manner that the part is maintained at a temperature which does not cause the formation of any film on the surface of the part. If the temperature of such a part is too low, however, the gaseous raw material undergoes precipitation on such a part and this in turn results in the formation of particles within the resulting film. The margin between the temperature at which the film-formation takes place and that at which the gaseous raw material undergoes precipitation is quite narrow. In particular, when forming a film of a multi-component compound such as PZT used for the manufacture of a ferroelectric memory, a plurality of raw materials should be used. In such case, the precipitation temperature of each raw material and the film-forming temperature thereof may variously vary depending on the plurality of raw materials used and the kinds of oxides of every elements used and therefore, a problem arises such that it is difficult to completely inhibit the occurrence of both precipitation and film-formation of the raw materials on the surface of a part such as a shower plate simply by the temperature control of the same.

Thus it is an object of the present invention to provide a thin film manufacturing apparatus, which can solve the problems associated with the foregoing conventional techniques and which is equipped with a new internal jig (such as shower plate) to be arranged within a film-forming chamber or the same internal jig used in a film-forming process and then washed and/or cleaned, the surface of which is covered with a specific film, in order to reduce the number of dummy substrates to be used prior to the practical film-forming operation, to reduce any change in the substrate temperature during the film-forming process and to reduce the changes in the composition and/or film thickness of the resulting thin film; a method for forming a ceramic thin film while using the thin film manufacturing apparatus; and a method for the manufacture of a semiconductor device using the ceramic thin film.

### Means For the Solution of the Problems

The thin film manufacturing apparatus of the present invention is one for manufacturing a ceramic thin film according to the thermal CVD technique and it is characterized in that an internal jig, which is provided with a film of a heat radiation material on the surface thereof, is arranged at a position facing the surface of a substrate, on which a desired film is to be formed.

As has been discussed above in detail, the formation of a film while using a thin film manufacturing apparatus which comprises an internal jig, arranged within the film-forming chamber and provided with a film of a heat radiation material on the surface thereof would permit the reduction of any change in the substrate temperature during the film-forming process, make the control of the substrate temperature easy and likewise permit the drastic reduction of the number of dummy substrates to be used in the preliminary step prior to the practical formation of an intended thin film.

According to an embodiment, the thin film manufacturing apparatus of the present invention is characterized in that the internal jig is at least one member selected from the group consisting of a shower plate and a part for mounting or attaching a shower plate.

According to another embodiment, the thin film manufacturing apparatus of the present invention is characterized in that at least one of the shower plate and the part for mounting or attaching a shower plate are set up while they are brought into close contact with a heating mechanism or a jig for exchanging heat, through which a liquid heating medium is circulated.

According to a still another embodiment, the thin film manufacturing apparatus of the present invention is characterized in that a thermocouple for determining the substrate temperature is placed within the apparatus, which is fixed while the tip thereof comes in close contact with the back surface of a substrate-supporting stage on which the substrate is to be placed, or which is fixed in the space in the proximity to the back surface of the stage.

According to a further embodiment, the thin film manufacturing apparatus of the present invention is characterized in that the film of the heat radiation material is one of a carbon-containing material selected from the group consisting of titanium carbide (TiC), titanium carbonitride (TiCN), chromium carbide (CrC), silicon carbide (SiC), and preferably carbon nanotubes such as carbon nanotube black body; an Al-containing material selected from the group consisting of aluminum nitride (AlN) and titanium aluminum nitride (TiAlN); a hydrocarbon resin; or a material comprising at least two of the foregoing materials. In addition, the ceramic thin film is preferably a PZT thin film.

The method for the preparation of a ceramic thin film according to the present invention comprises the steps of supplying, to the surface of a substrate arranged within a film-forming chamber, a film-forming gas which contains a reactive gas and a gaseous raw material obtained by gasifying a liquid containing a solid or liquid raw material dissolved in a solvent through the use of an evaporation system, or a gaseous raw material obtained through the sublimation of a solid raw material or the evaporation of a liquid raw material, through a gas introduction means; and forming a ceramic thin film on the surface of the substrate, which has been heated to a temperature of not less than the decomposition temperature of the gaseous raw material according to the thermal CVD technique, wherein the film-forming operation is carried out within a film-forming chamber provided with an internal jig which is to be arranged at a position within the chamber in such a manner that the jig faces the surface of the substrate and which is provided, on the surface thereof, with a film of a heat radiation material.

If a film is formed within the film-forming chamber provided with an internal jig which is arranged within the chamber in such a manner that it faces the substrate on which an intended film is to be deposited, and which is provided with a film of a heat radiation material on the surface thereof, the internal jig (for instance, a shower plate), which is arranged within the chamber in such a manner that it faces the substrate, can immediately radiate heat even when it is warmed due to the radiant heat emitted from the substrate. Therefore, the surface temperature of the substrate is certainly maintained at a constant level and any film identical to that formed on the substrate surface is never formed on the surface of the jig. This accordingly results in the substantial reduction of the number of dummy substrates to be used prior to the formation of a desired film on the substrate surface, and this also permit the solution of a problem such that the composition and/or the thickness (the film-forming rate) of the resulting ceramic film such as a PZT thin film are changed during the film-forming process.

According to an embodiment, the foregoing method for forming a ceramic thin film of the present invention is characterized in that the internal jig provided with a film of a heat radiation material on the surface thereof is at least one member selected from the group consisting of a shower plate and a part used for mounting or attaching a shower plate.

According to another embodiment, the ceramic thin film-forming method of the present invention is characterized in that the film-forming operation is carried out within the film-forming chamber in which at least one of the shower plate and the part for mounting or attaching a shower plate are set up while they are brought into close contact with a heating mechanism or with a heat-exchanging jig through which a liquid heating medium is circulated.

According to a still another embodiment, the ceramic thin film-forming method of the present invention is characterized in that the film of a heat radiation material is one made of a material selected from those listed above.

According to a further embodiment, the ceramic thin film-forming method of the present invention is characterized in that the solid and liquid raw materials are organometal compounds.

According to a still further embodiment, the ceramic thin film-forming method of the present invention is characterized in that the ceramic thin film formed according to the ceramic thin film-forming method is a film comprising lead zirconate titanate as a main component.

According to a still further embodiment, the ceramic thin film-forming method of the present invention is characterized in that the organometal compound used as a starting raw material for forming the film comprising lead zirconate titanate as a main component is one comprising Pb(thd)₂, Zr(dmhd)₄, and Ti(i-PrO)₂(thd)₂ in combination.

According to a still further embodiment, the ceramic thin film-forming method of the present invention is characterized in that the temperature of the surface of the shower plate is so controlled that it falls within the range of from 180 to 250° C.

According to a still further embodiment, the ceramic thin film-forming method of the present invention is characterized in that a new internal jig or a used and subsequently cleaned internal jig, which is provided with a film of a heat radiation material on the surface thereof, is fitted to the interior of the film-forming chamber before the initiation of the film-forming step and then the substrate is processed under the same film-forming conditions as those used for the film-forming step, as a preliminary film-forming step.

The method for the manufacture of a semiconductor device according to the present invention is a method for the formation of a semiconductor device which comprises a ceramic ferroelectric film and it is characterized in that the ferroelectric film is formed according to the foregoing ceramic thin film-forming method.

According to an embodiment, the semiconductor device manufacturing method of the present invention is one for the formation of a semiconductor device comprising a PZT ferroelectric film in which the ferroelectric crystals present in the ferroelectric film are mainly in the (111) oriented state, and the method is characterized in that the ferroelectric film is formed according to the foregoing ceramic thin film-forming method.

### Effects of the Invention

The thin film manufacturing apparatus according to the present invention is provided with an internal jig, which carries a film of a heat radiation material on the surface thereof, at a position facing the surface of the substrate on which an intended film is to be formed or on the side of the gas-introduction port of the substrate. Accordingly, the use of this thin film manufacturing apparatus would permit the considerable reduction of the number of dummy substrates used in the treating process of the preliminary film-forming step and the reduction of the fluctuations of the substrate temperature encountered during the film-forming operations, and the use thereof would likewise make the temperature control easy and permit the preparation of a desired product. Contrary to this, it was found that the use of any conventional thin film manufacturing apparatus, which was free of any internal jig used in the present invention, could never allow the stabilization of the film properties such as the thickness and composition of the resulting film in the practical film-forming process unless film-forming operations were repeated using not less than 100 dummy substrates in the treating process of the preliminary film-forming step. The use of the apparatus according to the present invention surely permits the achievement of a quite excellent effect such that the characteristic properties of the resulting film are stabilized after repeatedly carrying out the preliminary film-forming step using only 10 or less dummy substrates.

In addition, the ceramic thin film-forming method according to the present invention is implemented while using the aforementioned thin film manufacturing apparatus likewise according to the present invention. For this reason, the method of the present invention would permit the substantial reduction of the number of dummy substrates required for the preliminary film-forming step and the reduction of the fluctuations in the substrate temperature during the film-forming operations, and the use thereof likewise makes the temperature control easy and permits the preparation of a desired product.

Furthermore, the present invention also permits the achievement of an effect such that an excellent memory effect can be imparted to a semiconductor device such as a ferroelectric memory which comprises a ceramic thin film such as a PZT thin film.

### BRIEF DESCRIPTION OF THE DRAWINGS

FIG. 1 is a schematic block diagram schematically illustrating an exemplary construction of the thin film manufacturing apparatus according to the present invention.

FIG. 2 is a schematic block diagram schematically illustrating an exemplary construction of the shower plate peripheral parts of the thin film manufacturing apparatus according to the present invention.

FIG. 3 is a schematic block diagram schematically illustrating an exemplary construction of a multiple chamber-containing type thin film manufacturing apparatus which can be used in the present invention.

FIG. 4 is a graph showing the relation between the number of substrates treated and the substrate temperature (° C.) during the film-forming operations observed when forming a film while using the thin film manufacturing apparatuses according to the present invention and the conventional technique.

FIG. 5 is a graph showing the relation between the number of substrates treated and the film-forming rate (Å/min) during the film-forming operations observed when forming a film while using the thin film manufacturing apparatuses according to the present invention and the conventional technique.

FIG. 6 is a graph showing the relation between the number of substrates treated and the compositional ratio: Pb/(Zr+Ti) during the film-forming operations observed when films are formed using the thin film manufacturing apparatuses according to the present invention and the conventional technique.

FIG. 7 is a graph showing the relation between the number of substrates treated and the compositional ratio: Zr/(Zr+Ti) during the film-forming operations observed when films are formed using the thin film manufacturing apparatuses according to the present invention and the conventional technique.

### MODE FOR CARRYING OUT THE INVENTION

According to an embodiment of the thin film manufacturing apparatus relating to the present invention, there is provided an apparatus for forming a ceramic thin film according to the thermal CVD technique such as the MOCVD technique, wherein the apparatus is provided with internal jigs such as one of a shower plate and a part for mounting or securing a shower plate or both of a shower plate and a part for mounting or securing a shower plate, which are covered with a film of a heat radiation material on the surface thereof, at a position facing the substrate on which a desired film is to be deposited or a position on the side of the gas-introduction port of the substrate, wherein the internal jig is, if necessary, provided with a heating mechanism or a heat-exchangeable jig through which a liquid heating medium is circulated, in such a manner that the heating mechanism or the heat-exchangeable jig comes in close contact with the internal jig and wherein a thermocouple for determining the substrate temperature is placed within the apparatus, which is fixed to the apparatus while the tip thereof comes in close contact with the back surface of a substrate-supporting stage on which the substrate is to be placed, or which is fixed in the space in the proximity to the back surface of the stage.

For this reason, the fluctuations in the substrate temperature possibly observed during the formation of a film can considerably be reduced and this accordingly makes the control of the temperature of the substrate quite easy, this in turn permits the substantial reduction of the number of dummy substrates to be used in the pre-treatment upon the starting up of the film formation.

Specific examples of the foregoing films of the heat radiation materials include those each consisting of a carbon-containing material selected from the group consisting of titanium carbide (TiC), titanium carbonitride (TiCN), chromium carbide (CrC), silicon carbide (SiC), and carbon nanotubes such as a carbon nanotube black body; those each consisting of an Al-containing material selected from the group consisting of aluminum nitride (AlN), titanium aluminum nitride (TiAlN), alumina (Al₂O₃), and anodized aluminum (Al₂O₃); those each consisting of a hydrocarbon resin; or those each consisting of a material comprising at least two of the foregoing materials.

The foregoing film of the heat radiation material can be applied onto the surface of an intended internal jig as a coating film formed according to any known coating technique, or as a surface-modifying film formed according to the anodizing process (the formation of a superficial layer of an oxide film) as in the case of, for instance, anodized aluminum.

The heat radiation rate of the foregoing heat radiation materials are found to be as follows: 0.9 to 0.98 for titanium carbide, titanium carbonitride and chromium carbide; 0.8 to 0.9 for silicon carbide; 0.98 to 0.99 for carbon nanotube black body; 0.9 to 0.95 for aluminum nitride; 0.8 to 0.9 for anodized aluminum; and at least 0.08 for hydrocarbon resin. The fact that a material has a high heat radiation rate means that the material quite easily radiates heat immediately after the absorption thereof and that the material is liable to be easily cooled.

The abovementioned film of the heat radiation material can be formed on the surface of an object to be treated according to a method appropriately selected from the group consisting of, for instance, the plating technique, the evaporation technique, the CVD technique, the thermal spraying technique, the coating technique, and the anodic oxidation technique, depending on the kind of the object to be treated and the kind of the film to be formed. For instance, an anodized aluminum film can in general be formed by the surface-modification of an object according to the anodic oxidation technique (the formation of an aluminum oxide film). The anodized aluminum film herein used also includes an anodized aluminum film formed on the surface of an Al or Al-alloy material by the VACAL-OX (the registered trade mark granted for ULVAC TECHNO, Ltd.) special processing technique, in which the number of cracks formed during the treatment is considerably small as compared with that observed for the usual treating technique using an anodized aluminum film.

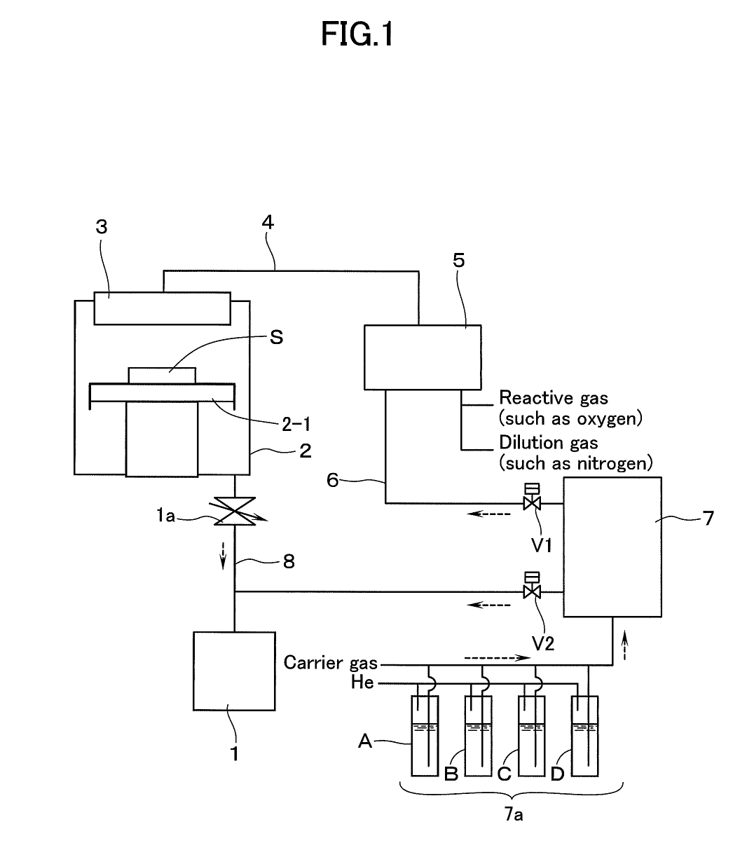

A CVD thin film manufacturing apparatus as an embodiment of the thin film manufacturing apparatus according to the present invention will hereunder be described in more detail with reference to the accompanying FIG. 1 which schematically shows the arrangement and construction of the CVD apparatus. In this connection, however, each part is shown, in each of the following attached figures, in such a manner that the degree of the reduced scale for the same is appropriately changed so that the size of each part will have a reasonable and recognizable one.

The CVD thin film manufacturing apparatus as shown in FIG. 1 comprises a film-forming chamber 2 which is connected to an evacuation system 1 through a pressure control valve 1a; a shower plate 3 which is positioned at the upper part of the film-forming chamber 2 as a means for the introduction of a gas; a gas-mixing unit 5 which is connected to the shower plate 3 through a film-forming gas-supplying pipe arrangement 4 having a predetermined length; and an evaporation unit 7 as an evaporation system, which is connected to the gas-mixing unit 5 through a gaseous raw material-supplying pipe arrangement 6.

The members constructing the apparatus including, for instance, the gas supply pipe arrangement, various kinds of valves and the gas-mixing unit arranged between the evaporation unit 7 and the film-forming chamber 2 are equipped with a heating means such as a heater or a heat-exchanger so that the gasified raw material can be maintained at a temperature at which the evaporated raw gas never undergoes any liquefaction, deposition, separation and/or formation of a film. The gaseous raw material-supplying pipe arrangement 6 arranged between the evaporation unit 7 and the gas-mixing unit 5 is provided with a valve V1, while a pipe arrangement 8 positioned between the evaporation unit 7 and the evacuation system 1 is equipped with a valve V2, and a pipe arrangement 8 extending from the evaporation unit 7 is connected to a pipe arrangement, in the middle thereof, which serves to connect the evacuation system 1 to the pressure control valve 1a. In other words, the thin film manufacturing apparatus is thus so designed that the evaporation unit 7, the gas-mixing unit 5 and the evacuation system 1 can be shut off from one to another. The thin film manufacturing apparatus is designed so as to have such a construction for the following reason: the evaporation unit 7, the gas-mixing unit 5 and the evacuation system 1 differ from one another in the maintenance cycle for every constituent elements thereof and accordingly, it should be inhibited for any substance such as moisture which adversely affect the film-forming operations to cause the adhesion to these constituent elements, when they are exposed or opened to the atmosphere upon the maintenance thereof. Thus, a specific constituent element can be opened to the atmosphere for the maintenance thereof, while the other two constituent elements are not exposed to the atmosphere at all and the latter two elements can certainly be maintained at their evacuated states.

Each of the constituent elements of the apparatus will now be described in more detail below.

The film-forming chamber 2 is so designed that it is provided therein with a substrate support stage 2-1 on which a substrate S as a subject for the deposition of a film is to be mounted and which has a means for heating the substrate (not shown) (this substrate support stage can serve as a so-called susceptor) and that a film-forming gas can be introduced into and guided towards the surface of the heated substrate through the shower plate 3. The evacuation system 1 permits the exhaustion of the excess film-forming gas which is not used in the film-forming reaction, the gaseous by-products generated during the reaction and the reactive gases. The shower plate 3 is appropriately heated and maintained at a temperature at which the gas introduced therein never undergoes any liquefaction, deposition, separation and/or film-formation.

The shower plate 3 positioned at the upper portion of the film-forming chamber 2 may be equipped with a particle-trapping unit serving as a filter for the capture of particles present in the film-forming gas. This particle-trapping unit may be arranged at a position immediately before the shower plate. In this respect, however, it is desirable that the temperature of the particle-trapping unit is appropriately maintained at a level which never causes any adhesion and capture of specific raw elements, in their gasified state, which are required for the intended reaction.

The use of the pressure control valve la arranged between the foregoing evacuation system 1 and the film-forming chamber 2 would permit the easy establishment of various film-forming pressure conditions.

The gas-mixing unit 5 serves to form a mixed gas of a gaseous raw material formed, a reactive gas and/or a dilution gas. To this end, the gas-mixing unit 5 is connected to the evaporation unit 7 through the gaseous raw material-supplying pipe arrangement 6 which is equipped with the valve V1 and the unit 5 is likewise connected to two gas sources (for instance, a source of a reactive gas such as oxygen gas and that of a dilution gas or an inert gas such as nitrogen gas) or gas supply means for these gases through valves, heat-exchangers and mass flow-controller (not shown). The reactive gas-supplying means is one for supplying an oxidizing gas such as oxygen gas, dinitrogen monoxide, and/or ozone gas, while the dilution gas-supply means is one for feeding, for instance, nitrogen gas or argon gas to the film-forming chamber.

There are introduced, into the gas-mixing unit 5, an oxidizing gas which is supplied from the reactive gas-supplying means and heated, in advance, to an appropriate temperature and a gaseous raw material which is generated in the evaporation unit 7 and supplied to the film-forming chamber through the gaseous raw material-supplying pipe arrangement 6 maintained at a temperature which never causes any liquefaction, deposition, separation and/or film-formation. These gases are uniformly blended together in the gas-mixing unit 5 and a film-forming gas (comprising an oxidizing gas and a gaseous raw material) can thus be formed in the gas-mixing unit 5. The gaseous raw material is a gas containing one or at least two kinds of gaseous raw materials. The film-forming gas thus prepared is introduced into the film-forming chamber 2 through the film-forming gas-supplying pipe arrangement 4 and the shower plate 3 in this order and then supplied onto the surface of a substrate as an object to be processed, which is mounted on the substrate-supporting stage 2-1, without forming any laminar flow within the film-forming chamber.

The foregoing film-forming gas-supplying pipe arrangement 4 may be connected to the gaseous raw material-supplying pipe arrangement 6 by means of a VCR joint and it is also possible that VCR gaskets for a part of the joints of the pipe arrangements are not simple rings, but may be VCR type particle-trapping units whose holes serve to capture particles. In this respect, it is desirable that each of the joint members, which is provided with such a VCR type particle-trapping unit is set and maintained at a temperature higher than that which does not cause any liquefaction and/or deposition (separation) of the gaseous raw material and that it is so designed that any gasified raw element required for the film-forming reaction are not adhered onto and captured by the member.

The film-forming gas-supplying pipe arrangement 4 positioned between the gas-mixing unit 5 and the shower plate 3 may likewise be equipped with a valve for switching the film-forming gases, on the secondary side of the gas-mixing unit 5. This valve is connected, on the downstream side thereof, to the film-forming chamber 2. This valve is opened when forming a film, while it is closed after the completion of the film-forming operation.

Connected to the evaporation unit 7 is a raw material-supplying zone or member 7a for the supply of a solution of an organometal compound in an organic solvent and the evaporation unit 7 serves to evaporate the raw material-containing liquid derived from the raw material-supplying zone 7a to thus form a raw gas. In this case, the raw material-supplying zone 7a is provided with tanks A, B, C and D which are filled with solutions of organometal compounds and organic solvents, respectively; pipe arrangements for the supply, under pressure, of an inert gas such as He gas to each tank; and a pipe arrangement for supplying carrier gas (for instance, an inert gas such as N₂ or Ar gas), which can convey or entrain the solutions of organometal compounds and the organic solvents which are forced out of the corresponding tanks by the action of the pressure of the gas for the pressure-supply. If the gas for the pressure-supply is fed to each tank through the gas-supplying pipe arrangement, the internal pressures within the tanks increase and as a result, the solutions of organometal compounds and the organic solvents are forced out of the tanks and introduced into the carrier gas-supplying pipe arrangement. The solutions of organometal compounds and the organic solvents forced out of the tanks in the form of droplets are introduced into the corresponding liquid flow rate controllers respectively to thus adjust the flow rate of each substance and then the latter is conveyed towards the evaporation unit 7 by the action of the carrier gas.

The evaporation unit 7 is so designed that it can efficiently heat and evaporate the droplets of the flow rate-controlled liquid raw material by a heating means to thus generate a gaseous raw material and that the resulting raw gas can be fed to the gas-mixing unit 5. This evaporation unit 7 permits the evaporation of a single liquid when the liquid raw material comprises a single raw material or the evaporation of a mixture of a plurality of solutions of raw materials when a plurality of liquid raw materials are required for the film-forming reaction. When evaporating the liquid raw material, it may be gasified by the following various techniques: a method in which heat is applied to the droplets of the liquid raw material to thus gasify the same; a method wherein the droplets are physically vibrated by blowing a gas upon the same to thus vaporize the droplets; a method in which ultrasonics are applied onto the droplets to gasify the same; or a method in which the droplets, previously been micronized by passing them through a fine nozzle, are introduced into the evaporation unit 7 to gasify the same. In this connection, it is desirable that any techniques of the foregoing techniques for gasifying the droplets are combined together to thus improve the evaporation efficiency. The evaporation unit 7 is preferably provided therein with an evaporation member made of a material having good thermal conductivity such as Al so that the droplets or liquid particles may efficiently be gasified even to an evaporation rate as high as possible, at the fixed place, and that the load required for the evaporation of liquid particles can be reduced by the use of various kinds of particle-trapping units.

Moreover, the evaporation unit 7 may be provided therein with a particle-trapping unit so as to inhibit the leakage, out of the evaporation unit, of the particles originated from the residue generated during the evaporation of the liquid raw material and so as to be able to evaporate the droplets entering into the unit as a tiny stream while preventing the droplets from being discharged out of the evaporation unit due to the action of a vacuum. The evaporation unit and the particle-trapping unit are desirably maintained at a well-controlled temperature so that the droplets or fine liquid particles which are brought into contact with these units can certainly be evaporated and that the specific elements of raw materials evaporated, which are required for the film-forming reaction and have been gasified, are never adhered onto and/or captured by these units.

In this respect, the foregoing raw material-supplying member 7a may be so designed that it has a tank D, which is filled with a solvent for the dissolution of the raw material and that the solvent can be introduced into the evaporation unit 7 while controlling the flow rate thereof by a flow rate controller to thus gasify the same and to thereby form a solvent gas. In this case, the solvent gas can be used for the cleaning of the interior of the apparatus.

As has been discussed above, the thin film manufacturing apparatus according to the present invention preferably comprises a cylindrical film-forming chamber 2 and the film-forming chamber 2 is provided therein with a cylindrical substrate-supporting stage 2-1 on which a substrate such as a silicon wafer can be mounted. A heating means (not shown) for heating such a substrate is assembled into the substrate-supporting stage 2-1. Moreover, the film-forming chamber 2 may be equipped with a means which is so designed that the substrate-supporting stage 2-1 can freely be moved, up and down, from the film-forming position within the chamber 2 to the substrate-conveying position at the lower part of the chamber. The apparatus according to the present invention is so designed that the shower plate 3 is placed at the upper and central portion of the film-forming chamber 2 such that it faces the substrate-supporting stage 2-1 and that the mixed gas or the film-forming gas from which particles have been removed can be injected towards the entire surface of the substrate through the shower plate 3. In this connection, the film-forming chamber 2 is connected to the evacuation system 1, which is provided with a dry vacuum pump or a turbo molecular pump, through the pressure-controlling valve 1a.

In the meantime, when thin film is formed on the surface of a substrate according to the CVD technique such as the MOCVD technique, the gaseous raw material is separated in the form of particles if the temperature of the gaseous raw material is reduced to a level of not more than the predetermined one and this may become a cause for the formation of film-forming dust. For this reason, the apparatus is preferably so designed that it is provided with a heat-exchanger as a means for controlling the temperature of a gas in the middle of each pipe arrangement for supplying, for instance, a gaseous raw material and it is likewise provided with a heating means such as a heater fixed to the outer wall of the film-forming chamber 2 and/or the substrate-supporting stage 2-1.

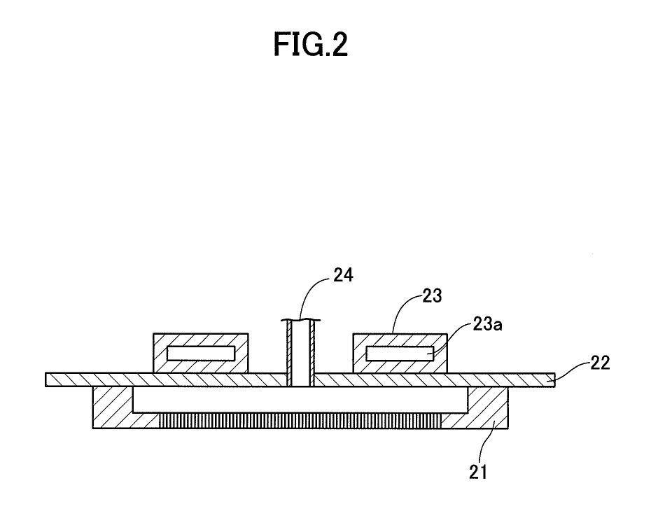

Then there will now be explained an embodiment relating to the peripheral portions of the shower plate of the thin film manufacturing apparatus according to the present invention while referring to FIG. 2.

FIG. 2 is a schematic block diagram schematically illustrating an exemplary construction of the peripheral parts of the shower plate, which consist of a shower plate 21, a flange for securing the shower plate and a heat-exchanging jig 23 through which a liquid heat medium 23a is circulated. In FIG. 2, the reference numeral 24 represents a gas introduction port. The shower plate 21 is preferably made of a material excellent in the heat conductivity. As such materials, there may be listed, for instance, at least one member selected from the group consisting of metals such as Al, Cu and Ti; alloys containing these metals; oxides of these metals; nitrides of these metals; SiC, AlN and carbon-containing substances (such as the aforementioned heat-radiation substances each containing a trace amount of carbon). Among these materials, preferably used herein is Al. In the case of the conventional techniques, the surface of the shower plate facing the substrate is a blast-treated one. The blast-treated surface of the conventional shower plate has a surface roughness almost identical to that attained by the cleaning step applied to the ceramic thin film such as a PZT thin film and carried out for the removal of undesirable thin films adhered to the surface of the shower plate during the film-forming process.

According to an embodiment of the ceramic thin film-manufacturing method of the present invention, there is provided a method for the formation of a ceramic thin film according to the thermal CVD technique such as the MOCVD technique and the method comprises the steps of supplying, to the surface of a substrate arranged within a film-forming chamber, a film-forming gas which contains a reactive gas serving as an oxidizing gas and a gaseous raw material obtained by gasifying a liquid containing a solid or liquid raw material (i.e. an organometal compound) dissolved in a solvent through the use of an evaporation system, or a gaseous raw material obtained through the sublimation of a solid raw material or the evaporation of a liquid raw material, through a gas introduction means; and forming a ceramic thin film mainly comprising, for instance, lead zirconate titanate while using a raw material consisting of organometal compounds, for instance, Pb(thd)₂, Zr(dmhd)₄, and Ti(i-PrO)₂(thd)₂, on the surface of the substrate, which has been heated to a temperature of not less than the decomposition temperature of the gaseous raw material, according to the thermal CVD technique, wherein the thin film is formed in a film-forming chamber provided with a jig which is placed therein while it faces the substrate on which the thin film is to be formed and the surface of which is covered with a film of the aforementioned substance having an excellent heat radiation ability or a film-forming chamber equipped with such an internal jig provided with a heating mechanism or a heat-exchangeable jig through which a liquid heat medium is circulated, wherein such a heating mechanism or heat-exchangeable jig is arranged in such a manner that it comes into close contact with the internal jig, and wherein the thin film is formed while controlling the temperature of the shower plate surface so as to fall within the range of from 180 to 250° C.

If a film is formed within the film-forming chamber provided with an internal jig which is arranged within the chamber in such a manner that it faces the substrate on which an intended film is to be deposited, and which is provided with a film of a heat radiation material on the surface thereof, the internal jig, which is arranged within the chamber in such a manner that it faces the substrate, can immediately radiate heat even when it is warmed due to the radiant heat emitted from the substrate during the film-forming process. Therefore, the surface temperature of the substrate is certainly maintained at a constant level and any film identical to that formed on the substrate surface is never deposited on the surface of the jig. This accordingly results in the substantial reduction of the number of dummy substrates to be used (for instance, the number of dummy substrates to be used is not more than 10) prior to the formation of a desired film on the substrate surface, and this also permit the occurrence of any variation in the composition and/or the thickness (the film-forming rate) of the resulting ceramic film such as a PZT thin film, during the film-forming process.

In the foregoing ceramic thin film-forming method, a new internal jig or a used and subsequently cleaned internal jig, which is provided with a film of a material having an excellent heat radiation ability on the surface thereof, is secured to the interior of the film-forming chamber, the internal temperature of the film-forming chamber is raised up to the film-forming temperature, and then substrates (dummy substrates) are continuously treated under the film-forming conditions identical to those used for the formation of an intended film, as a preliminary film-forming step, till the temperature of the every portions within the film-forming chamber is stabilized at a predetermined level.

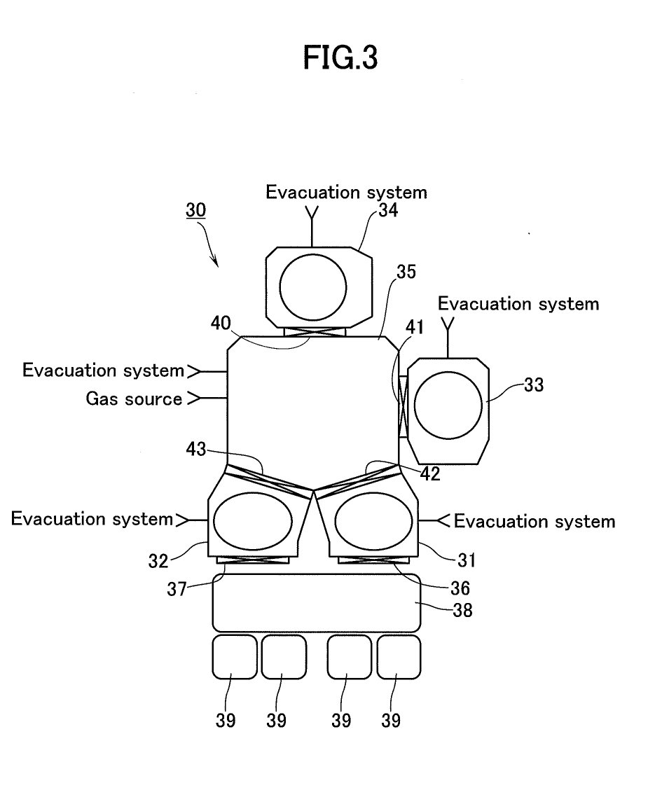

Next, a multi-chamber type thin film manufacturing apparatus used for the implementation of the method for the formation of a thin film according to the present invention will hereunder be described in more detail, with reference to FIG. 3 which schematically shows an embodiment thereof having an exemplary construction.

This thin film manufacturing apparatus 30 comprises stocker chambers 31 and 32 for the accommodation of substrates on which an intended thin film is to be formed (hereunder simply referred to as “substrate(s)”); processing chambers 33 and 34 for subjecting the substrate to a treatment for evacuating the apparatus to a desired vacuum; and a conveying chamber 35 for transferring the substrate from the stocker chambers 31 and 32 to the processing chambers 33 and 34 or vice versa.

The stocker chambers 31 and 32 have constructions identical to one another and they can accommodate therein a desired number (for instance, 25) of substrates. To the stocker chambers 31 and 32, there are connected evacuation systems such as dry vacuum pumps, respectively and they can independently be evacuated to a desired vacuum. It is a matter of course that only one evacuation system may be used for ensuring the same operations achieved by the use of two evacuation systems. The stocker chambers 31 and 32 are connected to an atmospheric substrate-conveying system 38 through gate valves 36 and 37, respectively. The atmospheric substrate-conveying system 38 is equipped with a substrate-conveying robot (not shown) for transferring substrates each free of any deposited film or substrates each carrying a deposited film between a wafer cassette 39 and the stocker chambers 31 and 32. In this connection, the thin film manufacturing apparatus of the present invention may comprise only one stocker chamber or may comprise a plurality of stocker chambers 31 and 32 like the apparatus as shown in FIG. 3.

Each of the processing chambers 33 and 34 may be constructed from, for instance, an etching chamber, a heating chamber or a film-forming chamber (such as a sputtering chamber or a CVD chamber), but the both processing chambers used in the embodiments of the present invention each are constructed from a film-forming chamber. The processing chambers 33 and 34 are connected to the corresponding evacuation systems, respectively and each evacuation system can independently be operated to establish a desired vacuum. It is a matter of course that only one evacuation system can be used to accomplish the operations identical to those achieved by the use of a plurality of evacuation systems. In the meantime, each of the processing systems 33 and 34 is connected, depending on each particular film-forming process, to gas sources such as a source of gaseous raw material as a desired film-forming gas and those of, for instance, a reactive gas and an inert gas, although they are not shown in this figure.

The conveying chamber 35 is provided with a substrate-conveying robot, although the robot is not shown in this figure and the chamber 35 is so designed that it can transfer substrates from the stocker chambers 31 and 32 to the processing chambers 33 and 34 or vice versa, or from the processing chamber 33 to the processing chamber 34 or vice versa. The conveying chamber 35 is connected to an evacuation system so that a vacuum can independently be established within the chamber. Moreover, the conveying chamber 35 is likewise so designed that a gas source is connected thereto so that the pressure within the chamber can be set at a predetermined level (higher than the pressure to be established in the processing chamber) due to the action of the pressure-controlling gas derived from the source thereof and introduced into the chamber. In addition, gate valves 40, and 41, and gate valves 42 and 43 are disposed between the conveying chamber 35 and the processing chambers 34, 33 and the stocker chambers 31, 32, respectively.

A desired number of wafers are transferred from the wafer cassette to the stocker chamber (31, 32) within the atmosphere and the stocker chamber is evacuated to a desired vacuum by the action of, for instance, a dry vacuum pump. The wafers are transferred from this stocker chamber to the processing chamber (33, 34) through the conveying chamber 35 which has previously been evacuated to a desired vacuum. In this respect, the method of conveying the wafers can be selected from the following two methods: a method in which the feeding of the gas to be introduced into the processing chambers (33, 34) is temporarily suspended or interrupted and then the substrates are conveyed in such a state; or a method in which an inert gas is passed through the conveying chamber 35 and the stocker chamber such that the pressure in these chambers are controlled to a level identical to or higher than that established in the processing chamber (33, 34) to thus hold the gas flow in the processing chamber (33, 34) and then the substrates are conveyed. The film-forming apparatus is thus so designed that the carrier gases including the gaseous raw material can flow through the discharge lines on the vent side and they can thus never flow into the processing chamber (33, 34).

The film-forming apparatus is equipped with two stocker chambers (31, 32) and if all of the wafers to be processed have entered into one of the stocker chamber, additional wafers can be introduced into the other stocker. In this way, if wafers are accommodated in the secondary stocker chamber, after the film-forming process for the wafers accommodated in the first stocker chamber are completed, the evacuation of the secondary stocker chamber is initiated, the substrates are again conveyed to the processing chamber (33, 34) after the evacuation is completed and then the film-forming operations are implemented.

Then, the relation between the number of substrates processed and the substrate temperature will hereunder be described, which will be observed when carrying out the film-forming process according to the method of the present invention. The film-forming operations were carried out under the following conditions, while using an apparatus (as shown in FIGS. 1 to 3) obtained by mounting or securing, to the aforementioned thin film manufacturing apparatus, a shower plate, which should be arranged so as to face the substrate mounted on the substrate-supporting stage and the surface of which had been covered with a TiAlN film, among the foregoing heat radiation films, formed according to the vapor deposition technique or a film of a hydrocarbon resin having a thickness ranging from 1 to 10 mm, likewise formed according to the vapor deposition technique.

More specifically, the film-forming operation was carried out using the foregoing thin film manufacturing apparatus provided with a shower plate whose surface is covered with the aforementioned film having an excellent heat radiation ability (hereunder referred to as “coated shower plate”) under the following process conditions: the gaseous raw material used: a gas generated using a solution of Pb(thd)₂, Zr(dmhd)₄, and Ti(i-PrO)₂(thd)₂ (in an amount of 25 mol/L each) in n-butyl acetate; the reactive gas used: oxygen gas; the carrier gas used: N₂ gas; and the film-forming pressure: 5 Torr (665 Pa).

The thin film manufacturing apparatus is provided with parts such as a shower plate and a deposition-inhibitory plate, and peripheral parts for the substrate, which have been subjected to a cleaning treatment, within the film-forming chamber prior to the film-forming operation. Used as such a shower plate to be arranged at the upper portion of the film-forming chamber is one subjected to a washing treatment with an organic solvent and to a physical blast cleaning treatment, or one subjected to these washing and cleaning treatments and then covered with the foregoing film excellent in the heat radiation ability. In addition, used herein as a substrate was one obtained by depositing an Ir film having a thickness of 70 nm according to the sputtering technique on a substrate covered with an SiO₂ film or layer, having a diameter of 8 inches.

With respect to the condition of the film-forming chamber prior to the film-forming operation, in other words, the condition of the film-forming chamber after the temperature of the interior of the film-forming chamber is raised to the intended film-forming temperature and the temperature of the entire parts in the chamber is stabilized and immediately before the first substrate is carried into the film-forming chamber, the gases other than the gaseous raw material from the evaporation unit and the carrier gas continuously flow through the apparatus at the same flow rates used when a film is formed and accordingly, the pressure in the film-forming chamber is maintained at a level required for the formation of a desired film and the substrate is set at a temperature identical to that used for forming a desired film. In addition, the conveying chamber is maintained at an evacuated condition while any gas never flows through the same.

When initiating the film-forming process, 25 wafers are transferred from a wafer cassette 39 accommodating 25 wafers to the stocker chamber (31, 32) by the operation of the robot situating on the side of the atmosphere. Subsequently, the interior of the stocker chamber is evacuated to a desired vacuum. Then the gate valves positioned between the stocker chamber (31, 32) and the conveying chamber 35 are opened to thus evacuate both of the conveying chamber and the stocker chamber by the action of the dry vacuum pump which has been operated to evacuate the conveying chamber. Thereafter, 1,800 sccm of nitrogen gas is introduced into the conveying chamber 35 to thus control the pressure in the conveying chamber to a level identical to (5 Torr (665 Pa)) or about 5% higher than that to be established in the processing chamber (33, 34) by operating an automatic pressure-control valve attached to the conveying chamber. After the control of the pressure in the conveying chamber 35 is almost or nearly completed, the first substrate present in the stocker chamber (31, 32) is carried into the processing chamber (33, 34) through the conveying chamber.

With respect to the evaporation unit, when the film-forming step is started, the flashing, with a solvent, of the nozzle of the evaporation unit is initiated and this would permit the evaporation of the solution of a raw material within about 3 minutes. At this stage, the evaporated gas is in such a condition that it is disposed through a vent line.

Immediately after the first wafer is transferred to the processing chamber (33, 34) and mounted on the substrate-supporting stage, the temperature of the substrate is raised and stabilized at a predetermined level within 3 minutes. The evaporation operation in the evaporation unit is switched or exchanged from the evaporation of the solvent to that of the film-forming material mainly comprising the solution of the raw material, whose flow rate is controlled, before 2 minutes from the convergence of the substrate temperature to a predetermined level (while the vent line is maintained or still in the operated state).

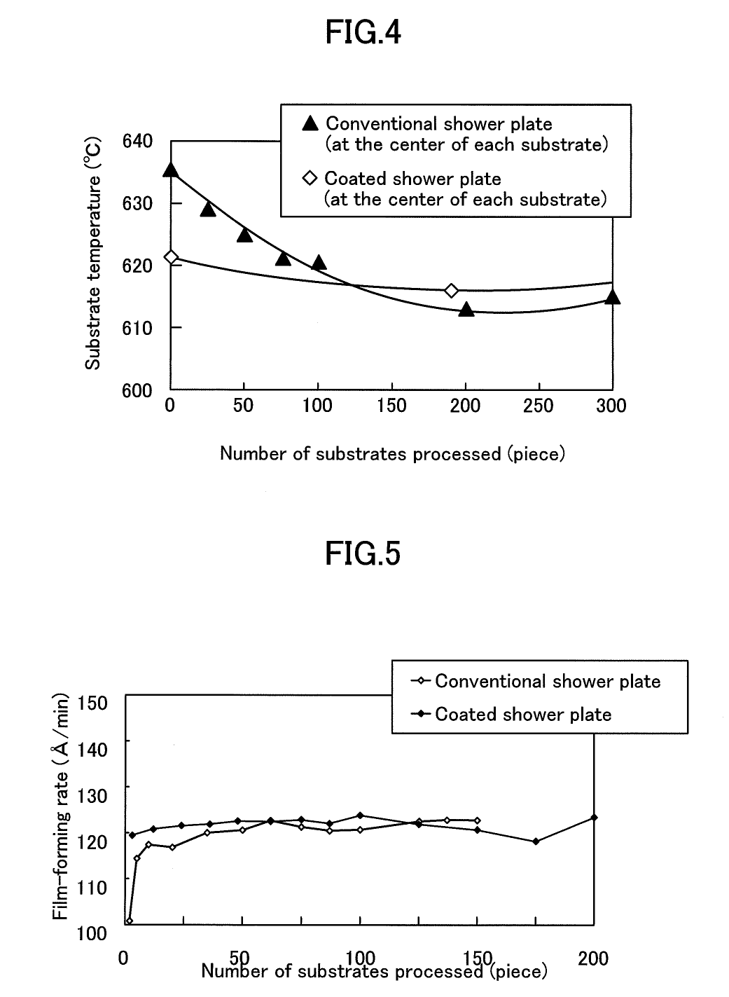

The results thus obtained are plotted on FIG. 4 in which the number of substrates treated during the film-forming operations (300 substrates in all) is plotted as abscissa and the variation in the substrate temperature (° C.) is plotted as ordinate. In this respect, the substrate temperature means that determined at the center of the substrate. As a control, the same film-forming processes implemented above are carried out using an apparatus provided with a conventional shower plate free of any heat radiation film (hereunder referred to as “conventional shower plate”).

As will be clear from the data plotted on FIG. 4, the established substrate temperature observed after increasing the temperature in the film-forming chamber and before initiating the film-forming operation, or the established substrate temperature observed when any substrate has not yet been subjected to any film-forming operation was found to be about 620° C. in the case of the apparatus provided with a coated shower plate, while the same temperature was found to be 635° C. in the case of the apparatus provided with the conventional shower plate. Accordingly, the difference in the established temperatures between these apparatuses is about 15° C. When the film-forming process is continued in such a situation to form films on 300 substrates, it can be recognized that the fluctuations in the substrate temperature are limited to a level of less than 5° C., for the film-forming process in which the apparatus provided with the coated shower plate is used and that this is quite low as compared with the fluctuations in the substrate temperature, on the order of about 20° C., observed for the film-forming process in which the apparatus provided with the conventional shower plate is used. Moreover, when using the apparatus provided with the conventional shower plate, the substrate temperature is not stabilized at a predetermined level unless not less than 100 substrates are processed in the preliminary film-forming step. On the other hand, it is clear that if using the apparatus provided with the coated shower plate according to the present invention, the substrate temperature is stabilized at a predetermined level only after not more than 10 substrates are processed in the preliminary step. The substrate temperatures observed when using the apparatuses provided with the coated shower plate and the conventional shower plate, respectively, converge on approximately the same level after 300 substrates are processed by these apparatuses.

As has been described above, when carrying out the film-forming operations while using the thin film manufacturing apparatus provided with the coated shower plate or the shower plate whose surface is covered with a film excellent in the heat radiation ability, the number of dummy substrates to be processed in the preliminary step can considerably be reduced, the fluctuations in the substrate temperature during the film-forming process are likewise reduced and the substrate temperature can thus be easily controlled, when comparing these results with those observed for the case in which the film-forming process is carried out using the apparatus provided with a shower plate whose surface is completely free of any film of a material having an excellent heat radiation ability and therefore, the use of the apparatus of the present invention would thus permit the stabilization of the characteristics such as thickness and composition of the thin film formed on the substrate surface.

Then the relation between the number of substrates treated and the film-forming rate (Å/min) will be described below in detail. Thin films were formed under the same conditions used above in connection with the foregoing explanation of the relation between the number of processed substrates and the substrate temperature, while using the thin film manufacturing apparatuses likewise identical to those used above.

The results thus obtained are plotted on FIG. 5 in which the number of substrates treated during the film-forming operations (150 and 200 substrates) is plotted as abscissa and the fluctuations in the film-forming rate are plotted as ordinate. As will be seen from the data plotted on FIG. 5, the film-forming rate observed when the film-forming process is carried out using the apparatus provided with the coated shower plate according to the present invention is maintained at almost the same level during the term when 3 to 200 substrates are continuously processed and this clearly indicates that the number of the dummy substrates to be used in the preliminary step is extremely small and that films having almost uniform thickness are formed. On the other hand, the film-forming rate observed when the film-forming process is carried out using the apparatus provided with the conventional shower plate is not stabilized even after about 75 substrates are processed and it can accordingly be recognized that a large number of dummy substrate is required in the preliminary step and that the thickness of the film formed during the film-forming process is fluctuated or is not stabilized.

Then the relation between the number of processed substrates and the compositional ratio: Pb/(Zr+Ti) or Zr/(Zr+Ti) will be described in more detail below. Thin films were formed under the same conditions used above in connection with the foregoing explanation of the relation between the number of processed substrates and the substrate temperature, while using the thin film manufacturing apparatuses likewise identical to those used above.

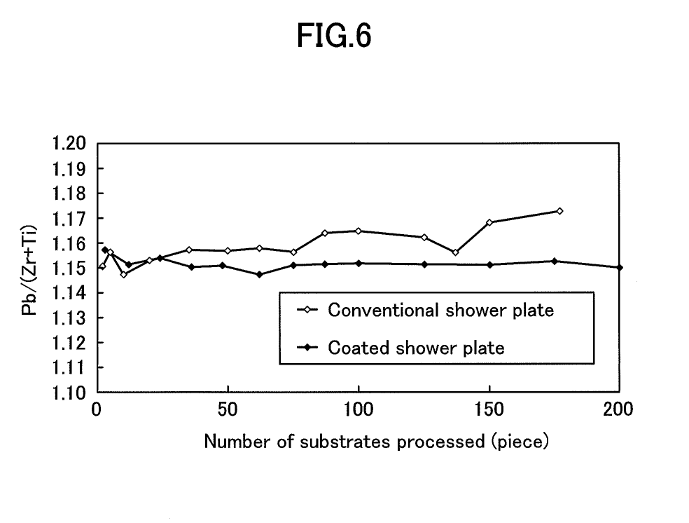

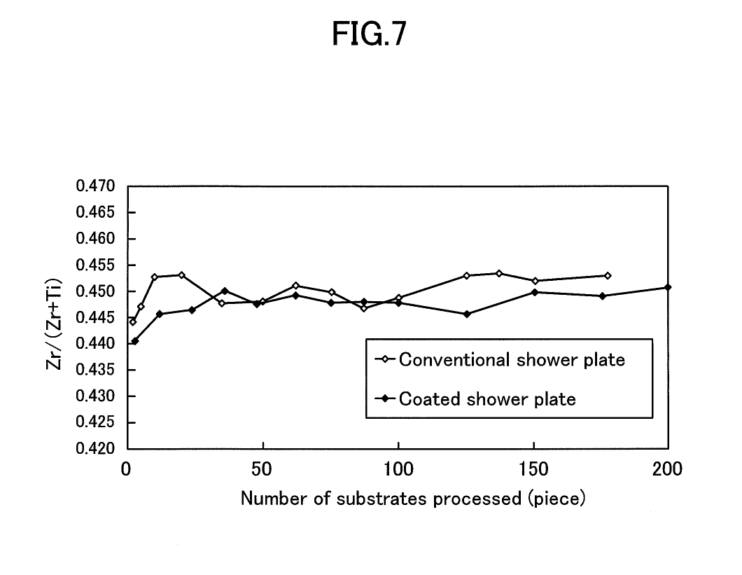

The results thus obtained are plotted on FIGS. 6 and 7 in which the number of processed substrates during the film-forming operations (about 175 and 200 substrates) is plotted as abscissa and the fluctuations in the compositional ratio: Pb/(Zr+Ti) or Zr/(Zr+Ti) are plotted as ordinate. FIG. 6 shows the relation between the number of processed substrates and the fluctuations in the compositional ratio: Pb/(Zr+Ti) and FIG. 7 shows the relation between the number of processed substrates and the fluctuations in the compositional ratio: Zr/(Zr+Ti).

As will be clear from the data plotted on FIGS. 6 and 7, each of the compositional ratios: Pb/(Zr+Ti) and Zr/(Zr+Ti) observed when the film-forming process is carried out using the apparatus provided with the coated shower plate according to the present invention is maintained at almost the same level during the term when 10 to 200 substrates are processed and this clearly indicates that the number of dummy substrates to be used in the preliminary film-forming step is extremely small and that films having almost uniform composition can be formed. On the other hand, each of the compositional ratios: Pb/(Zr+Ti) and Zr/(Zr+Ti) observed when the film-forming process is carried out using the apparatus provided with the conventional shower plate is not stabilized till the processing of about 50 substrates is completed and this clearly indicates that a large number of dummy substrates is required in the preliminary step, that at the same time, it is temporarily stabilized, but it becomes unstable immediately thereafter and that the fluctuations in the composition of the resulting film is not stabilized.

The coating film to be deposited on the jig according to the present invention is one consisting of the foregoing material having an excellent heat radiation ability. Important herein is that the coated film does not necessarily has a black external appearance under the irradiation with the visible light rays inasmuch as it is one consisting of a material which can form the surface of an internal jig such as a shower plate having an excellent heat radiation ability or a excellent heat-absorbing capacity with respect to the heat radiation originated from a substrate possibly heated to a temperature of not less than about 600° C. All of the films having an excellent heat radiation ability used in the present invention or the films prepared from the following material have a high rate of heat radiation and accordingly, the same results plotted on FIGS. 4 to 8, as has been discussed above (a TiAlN film and a hydrocarbon resin film are used as the coating films), can be obtained: the materials having an excellent heat radiation ability usable herein include, for instance, a carbon-containing material selected from TiC, TiCN, CrC, SiC, and carbon nanotubes, an Al-containing material selected from AlN and Al₂O₃, as well as a material comprising at least two of the foregoing materials in combination.

The film-forming temperature used when implementing the thin film manufacturing method according to the present invention is not limited to any specific one and it may be any known film-forming temperature used in the CVD technique such as the MOCVD technique. For instance, it is not higher than about 550° C. and preferably on the order of from about 450 to 550° C.

Moreover, the film formed according to the present invention may further be subjected to a crystallization-annealing treatment at a temperature lower than the film-forming temperature. For instance, when the film-forming temperature is 530° C., the film may be subjected to a crystallization-annealing treatment at a temperature extending from that of 110° C. lower than the film-forming temperature, preferably 80° C. lower than the film-forming temperature, and more preferably 50° C. lower than the film-forming temperature to the temperature in the proximity to the film-forming temperature and this would accordingly permit the satisfactory crystallization of the film and the formation of a thin film having desired electrical characteristics.

Thus, the use of the thin film manufacturing apparatus as shown in FIGS. 1 to 3 would permit the formation of an electrode film for capacitor while using an organometal compound containing, for instance, Pt, Ir and/or Ru as a source material. For instance, the use of such a thin film manufacturing apparatus permits the formation of a ferroelectric film or a PZT film using a liquid raw material such as Pb(thd)₂, Zr(dmhd)₄, and/or Ti(i-PrO)₂(thd)₂ according to the CVD technique; the formation of a film of PZT to which additional elements such as La, Sr, Ca and/or Al are added, according to the CVD technique; and the formation of a dielectric film having a high dielectric constant or a BST film using a liquid raw material such as Ba(thd)₂, Sr(thd)₄, and/or Ti(i-PrO)₂(thd)₂ according to the CVD technique. The use of such a thin film-forming apparatus would further permit the formation, according to the CVD technique, of a thin film mainly used as a metallic interconnection or distributing wire comprising Cu or Al; a film mainly used as a barrier comprising, for instance, TiN, TaN, ZrN, VN, NbN, or Al₂O₃; a dielectric thin film of, for instance, SBT or STO; and a film of such a dielectric material, to which an additional element such as La, Sr, Ca and/or Al are added.

### INDUSTRIAL APPLICABILITY

According to the present invention, any film is not formed on the surface of internal jigs used in a film-forming chamber. This in turn permits the substantial reduction of the number of dummy substrates to be used in the film-forming process as a preliminary film-forming step and this also makes, easy, the control of the substrate temperature when forming a thin film and the present invention can thus be applied to the fields, which make use of thin films, for instance, in the field of manufacturing semiconductor devices.

### EXPLANATION OF SYMBOLS

1 . . . evacuation system; 1a . . . pressure control valve; 2 . . . film-forming chamber; 2-1 . . . substrate-supporting stage; 3 . . . shower plate; 4 . . . pipe arrangement for film-forming gas; 5 . . . gas-mixing unit; 6 . . . pipe arrangement for supplying gaseous raw material; 7 . . . evaporation unit; 7a . . . raw material supply zone; 8 . . . pipe arrangement; 21 . . . shower plate; 22 . . . flange; 23 . . . heat-exchanging jig; 23a . . . liquid heat medium; 24 . . . gas-introduction port; 30 . . . film manufacturing apparatus; 31 . . . stocker chamber; 33, 34 . . . processing chamber; 35 . . . conveying chamber; 36, 37 . . . gate valve; 38 . . . atmospheric substrate-conveying system; 39 . . . wafer cassette; 40, 41, 42, 43 . . . gate valve; A, B, C, D . . . tank; S . . . substrate; V1, V2 . . . valve.

1. An apparatus for manufacturing a ceramic thin film according to the thermal CVD technique, characterized in that an internal jig, provided with a film of a heat radiation material on the surface thereof, is disposed at a position facing a substrate on which a desired thin film is to be formed.

2. The thin film manufacturing apparatus as set forth in claim 1, wherein the internal jig is at least one member selected from the group consisting of a shower plate and a part for mounting a shower plate.

3. The thin film manufacturing apparatus as set forth in claim 2, wherein at least one of the shower plate and the part for mounting a shower plate are set up, while they are brought into close contact with a heating mechanism or a heat-exchanging jig, through which a liquid heating medium is circulated.

4. The thin film manufacturing apparatus as set forth in claim 1, wherein a thermocouple for determining the substrate temperature is placed within the apparatus, which is fixed while the tip thereof comes in close contact with the back surface of a stage on which the substrate is to be placed, or which is fixed in the space in the proximity to the back surface of the stage.

5. The thin film manufacturing apparatus as set forth in claim 1, wherein the film of the heat radiation material is one prepared from a carbon-containing material selected from the group consisting of titanium carbide (TiC), titanium carbonitride (TiCN), chromium carbide (CrC), silicon carbide (SiC) and carbon nanotubes; from an Al-containing material selected from the group consisting of aluminum nitride (AlN) and titanium aluminum nitride (TiAlN); from a hydrocarbon resin; or from a material comprising at least two of the foregoing materials.

6. The thin film manufacturing apparatus as set forth in claim 1, wherein the ceramic thin film is a PZT thin film.

7. A method for the manufacture of a ceramic thin film according to the thermal CVD technique which comprises the steps of supplying, to the surface of a substrate arranged within a film-forming chamber, a film-forming gas which contains a reactive gas and a gaseous raw material obtained by gasifying a liquid containing a solid or liquid raw material dissolved in a solvent through the use of an evaporation system, or a gaseous raw material obtained through the sublimation of a solid raw material or the evaporation of a liquid raw material, through a gas introduction means; and forming a ceramic thin film on the surface of the substrate, which has been heated to a temperature of not less than the decomposition temperature of the gaseous raw material, according to the thermal CVD technique, wherein the film-forming operation is carried out within a film-forming chamber provided with an internal jig which is to be arranged at a position within the chamber in such a manner that the jig faces the substrate and which is provided, on the surface thereof, with a film of a heat radiation material.

8. The method for the manufacture of a ceramic thin film as set forth in claim 7, wherein the internal jig provided with a film of a heat radiation material on the surface thereof is at least one member selected from the group consisting of a shower plate and a part for mounting a shower plate.

9. The method for the manufacture of a ceramic thin film as set forth in claim 8, wherein the film-forming operation is carried out within the film-forming chamber in which at least one of the shower plate and the part for mounting a shower plate are set up while they are brought into close contact with a heating mechanism or with a heat-exchanging jig through which a liquid heating medium is circulated.

10. The method for the manufacture of a ceramic thin film as set forth in claim 7, wherein the film of the heat radiation material is one prepared from a carbon-containing material selected from the group consisting of titanium carbide (TiC), titanium carbonitride (TiCN), chromium carbide (CrC), silicon carbide (SiC) and carbon nanotubes; from an Al-containing material selected from the group consisting of aluminum nitride (AlN) and titanium aluminum nitride (TiAlN); from a hydrocarbon resin; or from a material comprising at least two of the foregoing materials.

11. The method for the manufacture of a ceramic thin film as set forth in claim 7, wherein the solid and liquid raw materials are organometal compounds.

12. The method for the manufacture of a ceramic thin film as set forth in claim 7, wherein the ceramic thin film is a film comprising lead titanate zirconate as a main component.

13. The method for the manufacture of a ceramic thin film as set forth in claim 12, wherein the organometal compound used as a starting material for forming the film comprising lead titanate zirconate as a main component is one comprising Pb(thd)₂, Zr(dmhd)₄, and Ti(i-PrO)₂(thd)₂ in combination.

14. The method for the manufacture of a ceramic thin film as set forth in claim 8, wherein the temperature of the surface of the shower plate is so controlled that it falls within the range of from 180 to 250° C.

15. The method for the manufacture of a ceramic thin film as set forth in claim 7, wherein a new internal jig or a used and subsequently cleaned internal jig, which is provided with a film of a heat radiation material on the surface thereof, is fitted to the interior of the film-forming chamber before the initiation of the film-forming step and then the substrate is treated under the same film-forming conditions as those used for the film-forming step, as a preliminary film-forming step.

16. A method for the manufacture of a semiconductor device comprising a ceramic ferroelectric film, characterized in that the ferroelectric film is formed according to the method for the manufacture of a ceramic thin film as set forth in claim 7.

17. A method for the manufacture of a semiconductor device comprising a PZT ferroelectric film in which the ferroelectric crystals present in the ferroelectric film are mainly in the (111) oriented state, wherein the ferroelectric film is formed according to the method for the manufacture of a ceramic thin film as set forth in claim 7.
